(19) United States
(12) Patent Application Publication
(10) Pub. No.: US 2024/0387309 A1
(43) Pub. Date: Nov. 21, 2024

(54) ELECTRONIC PACKAGE AND METHOD FOR FORMING THE SAME

(71) Applicant: STATS ChipPAC Pte. Ltd., Singapore (SG)

(72) Inventors: JinHee JUNG, Incheon (KR); ChangOh KIM, Incheon (KR); WooSoon KIM, Incheon (KR)

(21) Appl. No.: 18/661,773

(22) Filed: May 13, 2024

(30) Foreign Application Priority Data
May 19, 2023 (CN) 202310568818.2

(51) Int. Cl. H01L 23/31; H01L 21/56; H01L 23/498; H01L 23/552

(52) U.S. Cl. CPC H01L 23/3121; H01L 21/56; H01L 23/49822; H01L 23/552

(57) ABSTRACT

An electronic package is provided. The electronic package includes: a substrate comprising a substrate surface, and a first set of conductive patterns and a second set of conductive patterns on the substrate surface; at least one electronic component attached on the substrate surface and electrically connected to the second set of conductive patterns; an encapsulant layer encapsulating the at least one electronic component and exposing the first set of conductive patterns; and a shielding layer formed over the encapsulant layer and not over the first set of conductive patterns, wherein the shielding layer is formed of a conductive ink cured by ultraviolet light.

### TECHNICAL FIELD

The present application generally relates to electronic technology, and more specifically, to an electronic package and a method for forming an electronic package.

### BACKGROUND OF THE INVENTION

An electronic package may include various components with different shielding requirements. The production process of such electronic packages is complicated. Especially for a 5G antenna-in-package (AiP) product with a specific semiconductor package design, such as a partial molded system-in-package (SiP) structure, a selective shielding is required on a tight layout design, and the production efficiency of such package may be limited.

Therefore, a need exists for a method for forming an electronic package with a higher production efficiency.

### SUMMARY OF THE INVENTION

An objective of the present application is to provide a method for forming an electronic package with an improved production efficiency.

According to an aspect of embodiments of the present application, an electronic package is provided. The electronic package includes: a substrate comprising a substrate surface, and a first set of conductive patterns and a second set of conductive patterns on the substrate surface; at least one electronic component attached on the substrate surface and electrically connected to the second set of conductive patterns; an encapsulant layer encapsulating the at least one electronic component and exposing the first set of conductive patterns; and a shielding layer formed over the encapsulant layer and not over the first set of conductive patterns, wherein the shielding layer is formed of a conductive ink cured by ultraviolet light.

According to an aspect of embodiments of the present application, a method for forming an electronic package is provided. The method includes: providing a substrate comprising a substrate surface, a first set of conductive patterns and a second set of conductive patterns on the substrate surface; attaching at least one electronic component on the substrate surface to electrically connect the at least one electronic component with the second set of conductive patterns; forming an encapsulant layer over the at least one electronic component, wherein the encapsulant layer exposes the first set of conductive patterns; forming an ultraviolet curable conductive ink coating on the substrate to cover the encapsulant layer and the first set of conductive patterns; disposing an ultraviolet impervious mask above the first set of conductive patterns; curing the ultraviolet curable conductive ink coating by ultraviolet exposure to transform a portion of the ultraviolet curable conductive ink coating covering the encapsulant layer to a shielding layer; and removing the ultraviolet impervious mask and an uncured portion of the ultraviolet curable conductive ink coating from the substrate.

According to another aspect of embodiments of the present application, a method for forming an electronic package is provided. The method includes: providing a substrate comprising a substrate surface, a first set of conductive patterns and a second set of conductive patterns on the substrate surface; attaching at least one electronic component on the substrate surface to electrically connect the at least one electronic component with the second set of conductive patterns; forming an encapsulant layer over the at least one electronic component, wherein the encapsulant layer exposes the first set of conductive patterns; disposing a mask above the first set of conductive patterns; forming an ultraviolet curable conductive ink coating on the substrate to cover the encapsulant layer and the mask; curing the ultraviolet curable conductive ink coating by ultraviolet exposure; removing the mask and a portion of the conductive ink coating on the mask to expose the first set of conductive patterns and maintain a remaining portion of the conductive ink coating cured by ultraviolet light covering the encapsulant layer as a shielding layer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a cross-sectional view of an electronic package according to an embodiment of the present application.

FIGS. 2A to 2E illustrate cross-sectional views of steps of a method for forming an electronic package according to an embodiment of the present application.

FIGS. 3A to 3D illustrate cross-sectional views of steps of a method for forming an electronic package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

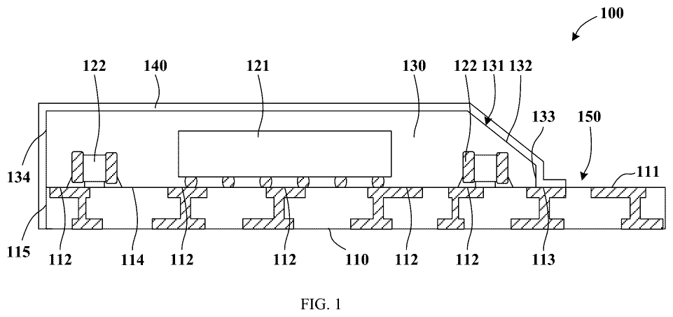

Referring to FIG. 1, an electronic package 100 according to an embodiment of the present application is shown. The electronic package 100 includes a substrate 110, which includes a substrate surface 114 having a first set of conductive patterns 111 and a second set of conductive patterns 112 thereon. In some embodiments, the substrate 110 may be a printed circuit board (PCB). In some embodiments, the substrate 110 may be a PCB and may include a redistribution structure (RDS) having one or more dielectric layers and one or more conductive layers between and through the dielectric layers (not shown). The conductive layers may define pads, traces, and plugs through which electrical signals or voltages can be distributed horizontally and vertically across the RDS. In some embodiments, the RDS may include a plurality of conductive patterns formed on both or either of the top and bottom surfaces of the substrate 110. It can be understood that the substrate may be other components for desired electronic connection of electronic components thereon. In some embodiments, the first and second sets of conductive patterns 111 and 112 may include different number of conductive patterns. In some embodiments, the first or second set of conductive patterns 111 and 112 includes patterned thin copper (Cu) foil. In some embodiments, the first or second set of conductive patterns 111 and 112 includes traces for routing signals and contacts for mounting devices.

Still referring to FIG. 1, the electronic package 100 also includes at least one electronic components such as electronic components 121, 122 attached on the substrate surface 114. The electronic components 121, 122 are electrically coupled to the second set of conductive patterns 112 respectively. The electronic components 121, 122 with the second set of conductive patterns 112 may or may not be electrically coupled to the first set of conductive patterns 111. In some embodiments, the first set of conductive patterns 111 may be electrically connected to other components, such as a board-to-board connector, and a part of the at least one electronic component 121, 122 and a part of the second set of conductive patterns 112 are electrically coupled to the first set of conductive patterns 111, for example, through the internal interconnect structures within the substrate 110. In some embodiments, the electronic components 121, 122 may include semiconductor dice, active electronic components such as bipolar or field effect transistors, or passive electronic components such as resistors, capacitors, or inductors. The passive and active electronic components can be electrically connected to form circuits, which enable the semiconductor package to perform high-speed calculations and other useful functions.

Still referring to FIG. 1, the electronic package 100 also includes an encapsulant layer 130 encapsulating the at least one electronic component 121, 122. The encapsulant layer 130 is not formed over the first set of conductive patterns 111 and thus exposing them for further connection with external devices. In some embodiments, the encapsulant layer 130 may be formed by depositing an encapsulant or molding compound on the substrate 110 using injection molding, compressive molding, transfer molding, liquid encapsulant molding, vacuum lamination, spin coating, or another suitable processes. The encapsulant layer 130 can be a polymer composite material, such as epoxy resin, epoxy acrylate, or any suitable polymer with or without filler. The encapsulant layer 130 may be non-conductive, provides structural support, and environmentally protects the electronic devices from external elements and contaminants. The encapsulant layer 130 may be formed with any shape as desired. In some embodiments, a lateral surface 134 of the encapsulant layer 130 may be aligned with a lateral surface 115 of the substrate 110, i.e., the encapsulant layer 130 may extend to the lateral surface 115 of the substrate 110. In some embodiments, the encapsulant layer 130 may be formed as a cube with substantially vertical lateral surfaces. In some other embodiments, the encapsulant layer 130 may be formed with sloped lateral surface as illustrated below.

Still referring to FIG. 1, the encapsulant layer 130 may take any form as desired. In some embodiments, the encapsulant layer 130 includes a lateral surface 131 having a sloped lateral portion 132 facing towards the first set of conductive patterns 111. In some embodiments, the lateral surface 131 further includes a foot portion 133 beneath and forming an angle with the sloped lateral portion 132 of the lateral surface 131 of the encapsulant layer 130. The foot portion 133 is in contact with the substrate surface 114. The lateral surface 131 of the encapsulant layer 130 with an obtuse angle may be easier for the encapsulant layer 130 to detach from its mold chase during a molding process for the encapsulant layer 130, for example, an injection molding process.

Still referring to FIG. 1, the electronic package 100 is also formed with a shielding layer 140 over the encapsulant layer 130, while the shielding layer 140 does not cover the first set of conductive patterns 111. In some embodiments, a narrow clearance 150 on the substrate surface 114 is formed spacing the shielding layer 140 from the first set of conductive patterns 111. In some embodiments, the shielding layer 140 is electrically grounded, for example, to a ground node of the electronic circuit system in the electronic package 100. In some embodiments, the shielding layer 140 also covers a lateral surface 115 of the substrate 110. Specifically, the shielding layer 140 is formed of a conductive ink cured by ultraviolet light. In some embodiments, the conductive ink curable by ultraviolet light reduces the cure temperature and cure time while maintaining good electric conductivity. In some embodiments, the conductive ink curable by ultraviolet light is curable at a low temperature, such as lower than 120° C. The conductive ink curable by ultraviolet light may form a smooth surface with a fine edge and a line resolution. The conductive ink curable by ultraviolet light also has long-term aging resistance and flexibility. In addition, the conductive ink curable by ultraviolet light may include no solvent and is therefore environmental friendly. In some embodiments, the conductive ink curable by ultraviolet light may have good electrical and thermal conductivities, to transmit electrical signals as well as to dissipate heat generated by the electronic components 121 and 122 to the environment. In some embodiments, the conductive ink curable by ultraviolet light may be 1-part epoxies, which is easy to dispense with screen printing or needle transfer, requiring no mixing. In some embodiments, the conductive ink curable by ultraviolet light may be 2-part epoxies, which has a relatively long shelf time, and may be cured at room temperature, or at higher temperatures with shorter curing times. In some embodiments, the shielding layer 140 has a thickness of 16 to 25 microns after being cured. In some embodiments, the shielding layer 140 is formed by spray coating or aerosol jet printing. Preferably, the shielding layer 140 is formed by spray coating which covers a relatively wide area and may achieve high throughput during production. In an example, the conductive ink curable by ultraviolet light may be product #FB2516-A commercially available from Polychem UV/EB International Corp. The product can be cured at a condition of a minimum power of 800 to 1,000 mJ/cm² by two high-pressure mercury ultraviolet lamps, and a post-cure heating condition of 120 to 150 centi-degrees for about 2 minutes. This product is preferably printed by a 250-300 mesh web. In another example, the conductive ink curable by ultraviolet light may be product Elecolit® Electrically and Thermally Conductive Adhesives #3063, #3064, #3065 commercially available from Panacol-Elosol GmbH. The products use 1-part ultraviolet acrylate as base, which has a curing condition of a power of 2000 mW/cm² and a pressure of 1.5 N/cm² for at least 15 seconds. It can be readily appreciated that any other conductive ink that is curable by ultraviolet can be used.

As can be seen, in the electronic package 100, the shielding layer 140 selectively covers the encapsulated layer 140 on the substrate 110, and the first set of conductive patterns 111 is exposed from the encapsulant layer 140 and is not covered by the shielding layer 140. Thereby, the first set of conductive patterns 111 is not electrically coupled to the shielding layer 140. In some embodiments, an another electronic component (not shown) may be electrically coupled to the first set of conductive patterns 111, optionally, the another electronic component may be electrically coupled to a component under the shielding layer 130 to achieve certain function or to achieve electrical connection to external components. The another electronic component may be desired to be not grounded. Since the shielding layer 140 is not electrically coupled to the first set of conductive patterns 111, the grounded shielding layer does not interfere with the functionality of the first set of conductive patterns 111.

Still referring to FIG. 1, in some embodiments, the substrate 110 also includes a third set of conductive patterns 113 in-between the first set of conductive patterns 111 and the second set of conductive patterns 112. In some embodiments, a lateral surface 131 of the encapsulant layer 130 may settle in an area of the third set of conductive patterns 113, and the shielding layer 140 may extend from the encapsulant layer 130 to the substrate surface 114 to at least partially cover the third set of conductive patterns 113. Preferably, the shielding layer 130 extends until an edge of the third set of conductive patterns 113 facing the first set of conductive patterns 111, such that a narrow clearance 150 on the substrate surface 114 is formed spacing the first set of conductive patterns 111 from the shielding layer 130. Thereby, the first set of conductive patterns 111 is not electrically coupled to the third set of conductive patterns 113 or the shielding layer 130. In some embodiments, the third set of conductive patterns 113 is electrically grounded. Thereby, the shielding layer 140 electrically coupled to the third set of conductive patterns 113 is also grounded. In some embodiments, the third set of conductive patterns 113 is electrically coupled to a component of the at least one electronic component 121 and 122 by such as electrical connection inside the substrate 110, such that the component of the at least one electronic component 121, 122 can be grounded as desired.

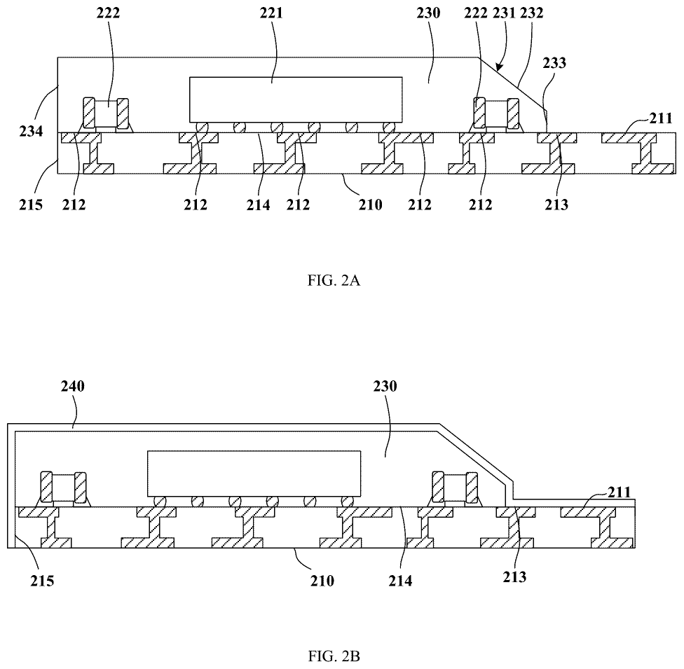

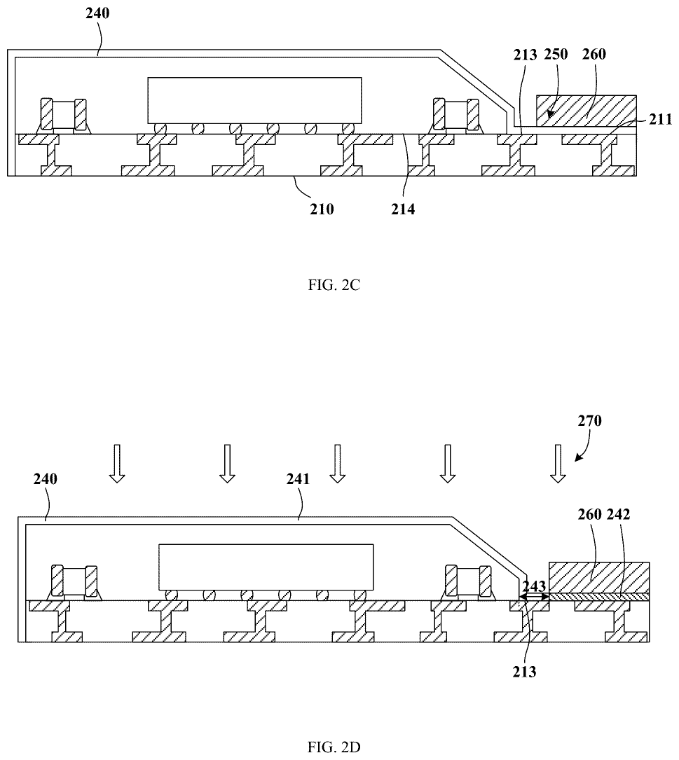

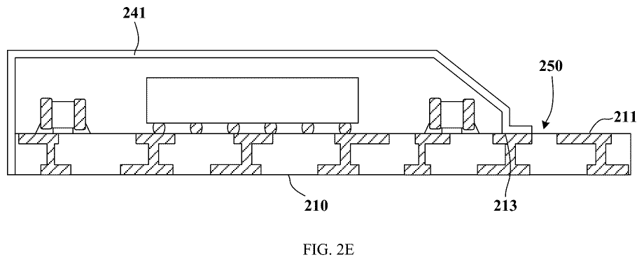

FIGS. 2A to 2E illustrate cross-sectional views of steps of a method for forming an electronic package according to an embodiment of the present application. For example, the method can be used to form the electronic package 100 shown in FIG. 1.

Referring to FIG. 2A, a substrate 210 is provided. The substrate 210 includes a substrate surface 214 including a first and second set of conductive patterns 211 and 212 thereon. In some embodiments, the substrate 210 further includes a third set of conductive patterns 213 in-between the first and the second set of conductive patterns 211 and 212. Also, at least one electronic component such as electronic components 221, 222 are attached on the substrate surface 214 to electrically connect the electronic components 221, 222 with the second set of conductive patterns 212. The configuration of the components may refer to the previous embodiments and will not be repeated herein.

Still referring to FIG. 2A, an encapsulant layer 230 is formed over the at least one electronic component 221, 222, and the encapsulant layer 230 exposes the first set of conductive patterns 211. In some embodiments, the first set of conductive patterns 211 remain exposed such that a further component may be attached thereon. In some embodiments, a lateral surface 234 of the encapsulant layer 230 may be aligned with a lateral surface 215 of the substrate 210 vertically. In some embodiments, the encapsulant layer 230 may include a lateral surface 231 having a sloped lateral portion 232 facing the first set of conductive patterns 211. In some embodiments, the lateral surface 231 may further include a foot portion 233 beneath the sloped lateral portion 232 and in contact with the substrate surface 214. The foot portion 233 may form an angle with the sloped lateral portion 232. The angles on the lateral surface 231 may be obtuse, which may be advantageous for the encapsulant layer 230 to detach from a mold chase during a molding process for forming the encapsulant layer 230. The configuration of the components may refer to the previous embodiments and will not be repeated herein.

Referring to FIG. 2B, an ultraviolet curable conductive ink coating 240 is formed on the substrate 210 to cover the encapsulant layer 230 and the first set of conductive patterns 211. In some embodiments, the ultraviolet curable conductive ink coating 240 may also cover a lateral surface 215 of the substrate 210. In some embodiments, the ultraviolet curable conductive ink coating 240 may also at least partially cover the third set of conductive patterns 213. In some embodiments, the ultraviolet curable conductive ink coating 240 may cover the entire substrate surface 214 that are not covered by the encapsulant layer 230. Preferably, the ultraviolet curable conductive ink coating 240 is formed by spray coating which may cover a relatively wide area and achieve high throughput.

Referring to FIG. 2C, an ultraviolet impervious mask 260 is disposed above the first set of conductive patterns 211. In some embodiments, the ultraviolet impervious mask 260 may be placed above the first set of conductive patterns 211 and does not touch the ultraviolet curable conductive ink coating 240. Thereby, the ultraviolet impervious mask 260 may be easily reused. In some embodiments, the ultraviolet impervious mask 260 may be a re-usable mask, such as at least one of film, metal and glass. In some embodiments, the re-usable mask may be film or glass including dark patterns of a designed shape, and the film or glass may be ultraviolet impervious. For example, the dark patterns may include chrome or black ink. In some other embodiments, the re-usable mask may be opaque material such as metal.

Still referring to FIG. 2C, in some other embodiments, the ultraviolet impervious re-usable mask may be an ultraviolet impervious part of a wafer-level or global mask which is partially ultraviolet pervious and partially ultraviolet impervious. For example, the wafer-level mask may be ultraviolet pervious at regions aligned with the first sets of conductive patterns of electronic packages on a wafer, and may be ultraviolet impervious at regions aligned with the encapsulant layers of the electronic package on the wafer. In some embodiments, the wafer-level mask may be made of a transparent material with dark patterns which are impervious to ultraviolet and formed at desired positions. In some embodiments, the wafer-level mask may be an ultraviolet impervious metal frame with multiple ultraviolet pervious cavities or holes. It can be understood that the re-usable mask or the wafer-level mask including the re-usable mask may also be disposed directly on the ultraviolet curable conductive ink coating 240, so long as the desired regions are ultraviolet impervious.

In some other embodiments, the ultraviolet impervious mask 260 may also be a disposable mask. The disposable mask may include at least one of tape or epoxy. In some embodiments, the disposable mask may be disposed directly on the ultraviolet curable conductive ink coating 240.

Still referring to FIG. 2C, the ultraviolet impervious mask 260 covers a same or a larger area than the first set of conductive patterns 211. For example, the ultraviolet impervious mask 260 may also cover a portion 250 on the substrate surface 214 adjacent to the first set of conductive patterns 211, such that after the process for forming the electronic package, the portion 250 may be formed with a narrow clearance spacing the first set of conductive patterns 211 from a shielding layer (not shown) formed in a subsequent step, as will be described below. In some embodiments, the ultraviolet impervious mask 260 may extend until above an edge of the third set of conductive patterns 213 facing the first set of conductive patterns 211.

Referring to FIG. 2D, the ultraviolet curable conductive ink coating 240 is cured by ultraviolet exposure 270 to transform a portion 241 of the ultraviolet curable conductive ink coating covering the encapsulant layer to a shielding layer 241. The portion 242 of the ultraviolet curable conductive ink coating 240 covered by the ultraviolet impervious mask 260 remains not exposed to the ultraviolet exposure 270, and is therefore not cured. In some embodiments, a portion 243 of the ultraviolet curable conductive ink coating 240 at least partially covering the third set of conductive patterns 213 is also transformed to a portion of the shielding layer 241 by ultraviolet exposure 270.

Referring to FIG. 2E, as compared to FIG. 2D, the ultraviolet impervious mask 260 is removed. Also, the uncured portion 242 of the ultraviolet curable conductive ink coating is removed. In some embodiments, the uncured portion 242 may be washed off together with the ultraviolet impervious mask 260 being removed. In some alternative embodiments, the mask 260 may be first detached from the substrate 210 and then the residual uncured portion 242 previously covered by the mask 260 may be further removed. In some embodiments, a narrow clearance 250 on the substrate 210 spacing the first set of conductive patterns 211 from the shielding layer 241 is formed. In some embodiments, the shielding layer 241 extends until an end of the third set of conductive patterns 213 facing the first set of conductive patterns 211, and the narrow clearance 250 on the substrate 210 extends between the first set of conductive patterns 211 and third set of conductive patterns 213 with the shielding layer 241. Thereby, the narrow clearance 250 ensures that the first set of conductive patterns 211 is not electrically coupled to the shielding layer 241.

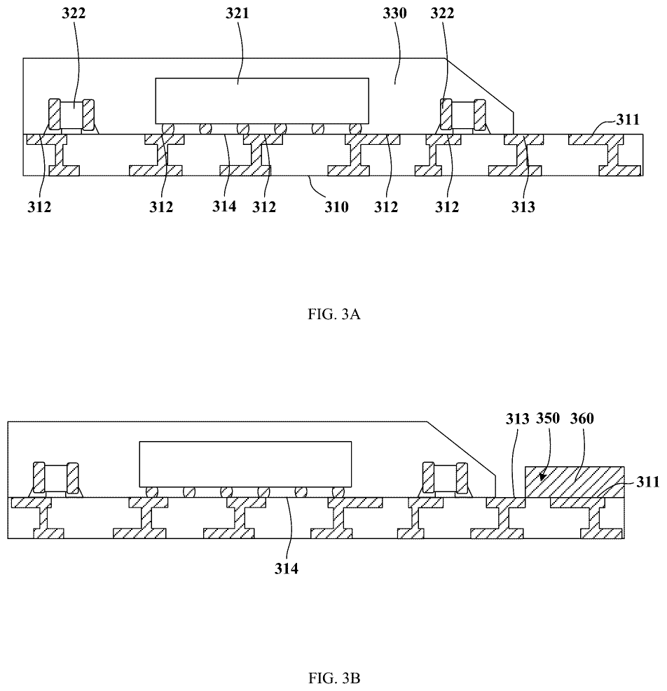

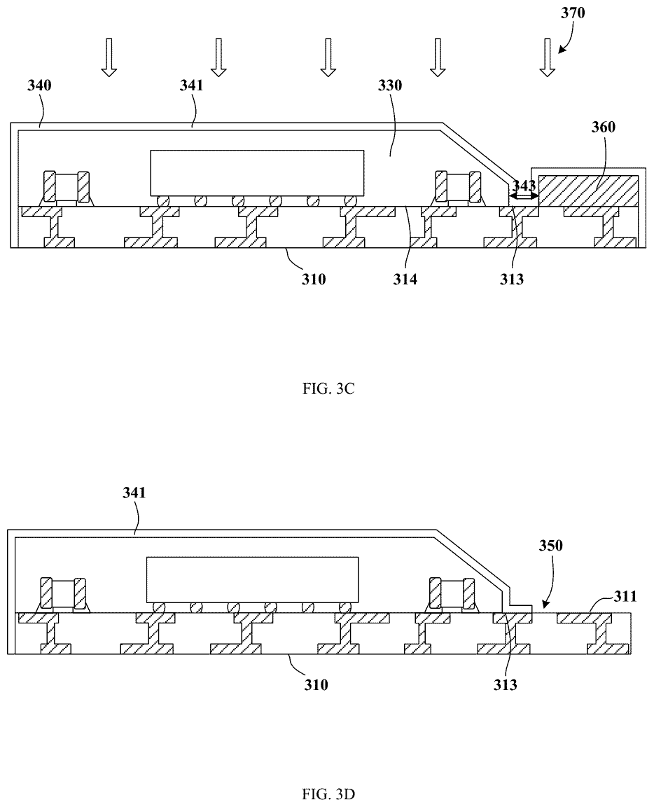

FIGS. 3A to 3D illustrate cross-sectional views of steps of a method for forming an electronic package according to another embodiment of the present application. For example, the method can be used to form the electronic package 100 shown in FIG. 1.

Referring to FIG. 3A, similar to FIG. 2A, a substrate 310 is provided. The substrate 310 includes a substrate surface 314 having a first set of conductive patterns 311 and a second set of conductive patterns 312 formed thereon. In some embodiments, the substrate 310 further includes a third set of conductive patterns 313 in-between the first and second sets of conductive patterns 311 and 312. Also, at least one electronic component such as electronic components 321, 322 is attached on the substrate surface 314 to electrically connect the electronic components 321, 322 with the second set of conductive patterns 312. An encapsulant layer 330 is also formed over the electronic components 321, 322, and the encapsulant layer 330 exposes the first set of conductive patterns 311. The configuration of the components may refer to the previous embodiments and will not be repeated herein.

Referring to FIG. 3B, different from FIG. 2B, a mask 360 is disposed above the first set of conductive patterns 311 prior to forming an ultraviolet curable conductive ink coating. In some embodiments, the mask 360 may be a disposable mask. The disposable mask may include at least one of tape or epoxy, and may have adhesive to improve the adhesivity to the substrate 310. In some embodiments, the mask 360 may be disposed directly on the substrate 310. In some embodiments, the mask 360 covers an area the same as or larger than that of the first set of conductive patterns 311. For example, the mask 360 may also cover a portion 350 of the substrate surface 314 which is adjacent to the first set of conductive patterns 311, such that after the process for forming the electronic package, the portion 350 may be formed with a narrow clearance spacing the first set of conductive patterns 311 from a shielding layer to be formed. In some embodiments, the ultraviolet impervious mask 360 may extend until above an edge of the third set of conductive patterns 313 facing the first set of conductive patterns 311.

Referring to FIG. 3C, an ultraviolet curable conductive ink coating 340 is formed on the substrate 310 to cover the encapsulant layer 330 and the mask 360. In some embodiments, the ultraviolet curable conductive ink coating 340 may also at least partially cover the third set of conductive patterns 313. In some embodiments, the ultraviolet curable conductive ink coating 340 may cover the entire substrate surface 314 that is not covered by the mask 360 and the encapsulant layer 330. Due to the existence of the mask 360, there is no conductive ink coating 340 formed on the first set of conductive patterns 311.

Still referring to FIG. 3C, the ultraviolet curable conductive ink coating 340 is cured by ultraviolet exposure 370 to partially transform the coating 340 to a shielding layer 341. In some embodiments, a portion 343 of the ultraviolet curable conductive ink coating 340 at least partially covering the third set of conductive patterns 313 is also transformed to a portion of the shielding layer 341 by ultraviolet exposure 370.

Referring to FIG. 3D, as compared to FIG. 3C, the mask 360 is removed. A cured portion of the ultraviolet curable conductive ink coating attached on the mask 360 is also removed with the mask 360. As such, the cured conductive ink coating may remain on the substrate 310 as a shielding layer 341, except on the first set of conductive patterns 311. A narrow clearance 350 on the substrate 310 spacing the first set of conductive patterns 311 from the shielding layer 341 is formed. In some embodiments, the shielding layer 341 extends until an end of the third set of conductive patterns 313 facing the first set of conductive patterns 311, and the narrow clearance 350 on the substrate 310 extends between the first set of conductive patterns 311 and third set of conductive patterns 313 with the shielding layer 341. Thereby, the narrow clearance 350 ensures that the first set of conductive patterns 311 is not electrically coupled to the shielding layer 341.

The discussion herein included numerous illustrative figures that showed various portions of an electronic package and method for making an electronic package. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic package, comprising:
a substrate comprising a substrate surface, and a first set of conductive patterns and a second set of conductive patterns on the substrate surface;
at least one electronic component attached on the substrate surface and electrically connected to the second set of conductive patterns;
an encapsulant layer encapsulating the at least one electronic component and exposing the first set of conductive patterns; and
a shielding layer formed over the encapsulant layer and not over the first set of conductive patterns, wherein the shielding layer is formed of a conductive ink cured by ultraviolet.

2. The electronic package of claim 1, wherein the encapsulant layer comprises a lateral surface having a sloped lateral portion facing towards the first set of conductive patterns.

3. The electronic package of claim 2, wherein the lateral surface of the encapsulant layer further comprises:
a foot portion beneath the sloped lateral portion of the lateral surface of the encapsulant layer, wherein the foot portion is in contact with the substrate surface; and
wherein the foot portion forms an angle with the sloped lateral portion.

4. The electronic package of claim 1, wherein the substrate further comprises a third set of conductive patterns in-between the first set of conductive patterns and the second set of conductive patterns, and wherein the shielding layer extends from the encapsulant layer to the substrate surface to at least partially cover the third set of conductive patterns.

5. The electronic package of claim 1, wherein a thickness of the shielding layer is 16 to 25 microns.

6. A method for forming an electronic package, comprising:
providing a substrate comprising a substrate surface, a first set of conductive patterns and a second set of conductive patterns on the substrate surface;
attaching at least one electronic component on the substrate surface to electrically connect the at least one electronic component with the second set of conductive patterns;
forming an encapsulant layer over the at least one electronic component, wherein the encapsulant layer exposes the first set of conductive patterns;
forming an ultraviolet curable conductive ink coating on the substrate to cover the encapsulant layer and the first set of conductive patterns;
disposing an ultraviolet impervious mask above the first set of conductive patterns;
curing the ultraviolet curable conductive ink coating by ultraviolet exposure to transform a portion of the ultraviolet curable conductive ink coating covering the encapsulant layer to a shielding layer; and
removing the ultraviolet impervious mask and an uncured portion of the ultraviolet curable conductive ink coating from the substrate.

7. The method of claim 6, wherein forming an encapsulant layer comprises forming a lateral surface of the encapsulant layer having a sloped lateral portion facing towards the first set of conductive patterns.

8. The method of claim 7, wherein forming a lateral surface of the encapsulant layer further comprises:
forming the lateral surface of the encapsulant layer having a foot portion beneath the sloped lateral portion of the lateral surface and in contact with the substrate surface; wherein the foot portion forms an angle with the sloped lateral portion.

9. The method of claim 6, wherein the substrate further comprises a third set of conductive patterns in-between the first set of conductive patterns and the second set of conductive patterns;
wherein forming an ultraviolet curable conductive ink coating on the substrate further comprises: forming the ultraviolet curable conductive ink coating on the substrate to at least partially cover the third set of conductive patterns; and
wherein curing the ultraviolet curable conductive ink coating further comprises curing the ultraviolet curable conductive ink coating by ultraviolet exposure to transform a portion of the ultraviolet curable conductive ink coating at least partially covering the third set of conductive patterns to a portion of the shielding layer.

10. The method of claim 6, wherein a thickness of the shielding layer is 16 to 25 microns.

11. The method of claim 6, wherein forming an ultraviolet curable conductive ink coating on the substrate comprises spray coating.

12. The method of claim 6, wherein the ultraviolet impenetrable mask is a re-usable mask or a disposable mask.

13. The method of claim 12, wherein the re-usable mask comprises at least one of film, metal and glass.

14. A method for forming an electronic package, comprising:
providing a substrate comprising a substrate surface, a first set of conductive patterns and a second set of conductive patterns on the substrate surface;
attaching at least one electronic component on the substrate surface to electrically connect the at least one electronic component with the second set of conductive patterns;
forming an encapsulant layer over the at least one electronic component, wherein the encapsulant layer exposes the first set of conductive patterns;
disposing a mask above the first set of conductive patterns;
forming an ultraviolet curable conductive ink coating on the substrate to cover the encapsulant layer and the mask;
curing the ultraviolet curable conductive ink coating by ultraviolet exposure;
removing the mask and a portion of the conductive ink coating on the mask to expose the first set of conductive patterns and maintain a remaining portion of the conductive ink coating cured by ultraviolet light covering the encapsulant layer as a shielding layer.

15. The method of claim 14, wherein forming an encapsulant layer comprises forming a lateral surface of the encapsulant layer having a sloped lateral portion facing towards the first set of conductive patterns.

16. The method of claim 15, wherein forming a lateral surface of the encapsulant layer further comprises:
forming the lateral surface of the encapsulant layer having a foot portion beneath the sloped lateral portion of the lateral surface and in contact with the substrate surface; wherein the foot portion forms an angle with the sloped lateral portion.

17. The method of claim 14, wherein the substrate further comprises a third set of conductive patterns in-between the first set of conductive patterns and the second set of conductive patterns;
wherein forming an ultraviolet curable conductive ink coating on the substrate further comprises: forming the ultraviolet curable conductive ink coating on the substrate to at least partially cover the third set of conductive patterns; and
wherein curing the ultraviolet curable conductive ink coating further comprises curing the ultraviolet curable conductive ink coating by ultraviolet exposure to transform a portion of the ultraviolet curable conductive ink coating at least partially covering the third set of conductive patterns to a portion of the shielding layer.

18. The method of claim 14, wherein a thickness of the shielding layer is 16 to 25 microns.

19. The method of claim 14, wherein forming an ultraviolet curable conductive ink coating on the substrate comprises spray coating.

20. The method of claim 14, wherein the mask is a disposable mask.
